(19) United States
(12) Patent Application Publication
(10) Pub. No.: US 2016/0105995 A1
(43) Pub. Date: Apr. 14, 2016

(54) COOLING AIR SYSTEM AND SPLASH-WATER PROTECTION ARRANGEMENT FOR A COOLING AIR SYSTEM OF A HOUSING

(71) Applicant: SMA SOLAR TECHNOLOGY AG, Niestetal (DE)

(72) Inventor: Andreas Falk, Kassel (DE)

(21) Appl. No.: 14/880,506

(22) Filed: Oct. 12, 2015

(30) Foreign Application Priority Data
Oct. 14, 2014 (DE) 10 2014 114 900.9

(51) Int. Cl. H05K 7/20; H02M 7/42

(52) U.S. Cl. CPC H05K 7/20181; H05K 7/20127; H02M 7/42; H05K 7/20909

(57) ABSTRACT

The disclosure relates to a splash-water protection arrangement for a cooling air system of a housing of an electrical or electronic device having an air box having an air inlet grille and an air outlet opening through which air outlet opening ambient air sucked in at the front side exits the air box. The air inlet grille has a multiplicity of profiled strips that are arranged in at least two planes lying one behind the other in a main air inflow direction, wherein the profiled strips lying within a plane are spaced apart from one another and the profiled strips lying in the various planes overlap laterally.

### CROSS REFERENCE TO RELATED APPLICATIONS

This application claims priority to German Application No. 10 2014 114 900.9, filed on Oct. 14, 2014, and incorporated herein by reference in its entirety.

### FIELD

The disclosure relates to a splash-water protection arrangement for a cooling air system of a housing of an electrical or electronic device, in particular of a power inverter.

### BACKGROUND

Electronic or electrical devices which are installed within a housing are frequently cooled with ambient air which is sucked in from the surroundings of the housing into the interior of the housing and is conducted past heat-generating electrical and/or electronic components of the device within the interior of the housing, for example through a cooling air duct, in order to cool said components. In particular in the case of devices which are used in external areas such as, for example, power inverters of photovoltaic outdoor installations, it is necessary to ensure here that sprayed water does not enter or as far as possible no splash water or rain water is sucked into the cooling system with the ambient air. Water which is introduced could bring about insulation problems and result in increased corrosion of components which are arranged in the cooling air stream.

In order to protect against the ingress of sprayed water or splash water, air is let into the housing of the device through an air inlet grille of the type mentioned at the beginning, which is integrated into one of the walls of the housing.

Such an air inlet grille is known, for example, from document DE 26 33 585 A1. In the air inlet grille, profiled strips, for example with a v-shaped profile, are arranged one behind the other in at least two planes (rows). The profiled strips in the different planes are arranged offset with respect to one another here with the result that sprayed water or splashed water cannot directly enter, in a straight line from the outside, the cooling air system which extends further. The profiled strips form a type of cooling air labyrinth in which the sucked-in ambient air is deflected about the profiled strips which overlap laterally. Since water cannot satisfactorily follow this deflection owing to its inertia, it is intercepted by the profiled strips and can run off downwards on the profiled strips into a run-off region. The same also applies to a large number of dust particles or dirt particles which are sucked in with the ambient air. Owing to their inertia, the latter are also intercepted to a large extent by the profiled strips, and direct ingress of dust particles or dirt particles into the interior of the housing of the device with the ambient air is prevented or at least significantly reduced.

In order to form effective protection against the ingress of sprayed water or splash water, the profiled strips are arranged relatively close to one another. Correspondingly, such an air inlet grille constitutes a large flow resistance. In order to avoid adversely affecting the cooling air stream to too great a degree and in order to achieve good cooling with as little expenditure of energy as possible for cooling air fans, the surface of the air inlet grille must be selected to be sufficiently large in relation to the surface of the adjoining cooling air duct (or cooling air fan). However, a surface of the desired size is not necessarily available in housings of electrical or electronic devices. In addition, enlargement of the surface of the air inlet grille entails increased expenditure in terms of materials and therefore increased costs.

### SUMMARY

The present disclosure is directed to a splash-water protection arrangement, a cooling air system or an electrical or electronic device of the type mentioned at the beginning which provide good protection against splash water while requiring the smallest possible air inlet area and with a low flow resistance at the same time.

A splash-water protection arrangement of the type mentioned at the beginning is defined by the fact that at least one air inlet opening is arranged laterally next to the air inlet grille in the front side of the air box, wherein a dividing wall which extends from the front side of the air box into the interior of the air box is arranged between the air inlet grille and the air inlet opening, through which dividing wall direct ingress of splash water or sprayed water through the air inlet opening into the air outlet opening is prevented.

The disclosure is based on the concept that an air inlet opening without an air inlet grille mounted in front or air labyrinth mounted in front can be arranged laterally next to the air inlet grille, since direct ingress of splash water or sprayed water can be prevented easily and with low expenditure on materials by the dividing wall which extends into the interior of the air box. The dividing wall forms, to a certain extent with the external regions of the air box, an air labyrinth which is arranged downstream of the air inlet opening. Eddying, associated with the dividing wall, of the cooling air stream on its path between the air inlet opening, arranged laterally next to the air inlet grille, and the air outlet opening, is low. Therefore, the pressure loss of the cooling air stream can also be reduced significantly relative to a state in which the entire front side of the splash-water protection arrangement is covered by the air inlet grille which is mounted in front.

In one advantageous refinement of the splash-water protection arrangement, the dividing wall extends so far into the interior of the air box that a free edge of the dividing wall lies in the main air inflow direction behind a virtual straight connection between a point at the edge of the air inlet opening and a point at the edge of the air outlet opening. In one embodiment this applies to the entire length of the free edge, but at least for a significant part of the edge length of the free edge. If this geometric condition for the depth of the dividing wall is complied with, the direct ingress of splash water or sprayed water into the cooling air system is precluded if the splash water or sprayed water does not deviate from the airstream of a virtual straight trajectory.

However, in a real case, particles of the splash water or sprayed water experience deflection or deviation from the virtual straight trajectory as a function of their particle size or inertia which is associated with their particle size. This deviation arises from a force effect on the particles of the splash water or sprayed water, which in effect is caused by a difference between a direction of the airflow and a direction of flight of the particles at each location. In order also to take into account such deviation of the particles to reduce further their ingress into the interior of the housing, the depth to which the dividing wall extends into the air box can be selected to be larger than is necessary for the fulfilment of the specified criterion, for example at least 10% larger or advantageously at least 20% larger.

In a further advantageous refinement of the splash-water protection arrangement, an air inlet opening with an assigned dividing wall is arranged on each of the two sides next to the air inlet grille, optionally also above and/or below. In this way, the available space next to the air inlet grille can be utilized as well as possible, and the ratio between the installation space and the pressure loss of the splash-water protection arrangement can be optimized further.

In a further advantageous refinement of the splash-water protection arrangement, the air inlet grille and the air outlet opening or the air outlet openings are arranged in planes which are oriented parallel to one another. Within these planes, the air inlet grille is positioned laterally centred relative to the air outlet opening or relative to the air outlet openings. In this context, the air inlet grille preferably projects laterally beyond the air outlet opening, in one embodiment by at least 50% of the width of the air outlet opening. In this way it is ensured that perpendicularly occurring splash water or sprayed water impacts next to the air outlet opening against a rear wall of the air box from where it can run off. The further the air inlet grille projects laterally beyond the air outlet opening, the shorter the selection which can be made for the dividing wall, the dividing wall intercepting obliquely impinging splash water or sprayed water. In the case of a relatively short dividing wall, the air resistance of the air labyrinth which is formed from the air opening, air box side wall and air box rear wall and dividing wall is in turn lower.

In a further advantageous refinement of the splash-water protection arrangement, the profiled strips of the air inlet grille run essentially parallel to one another. In one embodiment they run vertically with respect to the direction of their longitudinal extent, in order to simplify the running off of intercepted water. The profiled strips of the air inlet grille have a groove-shaped, for example a v-shaped or a u-shaped, profile, wherein in one embodiment the profiled strips are oriented in opposite directions to one another in the two planes with respect to their profile. An air resistance which is as low as possible is achieved by means of the specified profile geometries. In addition, with the specified profiling, water can run off downwards particularly well without being carried along to the side by the airstream.

In a further advantageous refinement of the splash-water protection arrangement at least one air baffle is arranged between at least one dividing wall and the side wall which is adjacent to the at least one dividing wall, wherein the at least one air baffle is oriented essentially parallel to the dividing wall and is positioned in such a way that it has an intersection point with the virtual straight connection between a point at the edge of the air inlet opening and a point at the edge of the air outlet opening. The at least one air baffle constitutes additional protection against obliquely impinging splash water and sprayed water, wherein owing to its orientation and positioning said air baffle only brings about a small, tolerable increase in the overall pressure loss.

An inventive cooling air system of a housing of an electrical or electronic device, in particular of a power inverter, has such a splash-water protection arrangement, wherein in one embodiment the front side of the air box of the splash-water protection arrangement is formed by a section of a front wall, of a rear wall and/or of a side wall of the housing. An electrical or electronic device according to the disclosure, in particular a power inverter, having a housing, is defined by such a cooling air system. In each case the advantages specified in conjunction with the splash-water protection arrangement are obtained.

### BRIEF DESCRIPTION OF THE DRAWINGS

The disclosure will be explained in more detail below by means of example embodiments and using figures, in which:

FIG. 1 shows a schematic sectional illustration of a first example embodiment of a splash-water protection arrangement for a cooling air system;

FIGS. 2, 3 each show an isometric illustration of a splash-water protection arrangement in a second example embodiment from various viewing angles; and

FIG. 4 shows a plan view of the front side of the splash-water protection arrangement of the second example embodiment.

### DETAILED DESCRIPTION

The disclosure relates to a splash-water protection arrangement for a cooling air system of a housing of an electrical or electronic device, in particular of a power inverter. The splash-water protection arrangement has an air box which has an air inlet grille on an outwardly pointing front side and an air outlet opening on a rear side lying opposite, through which air outlet opening the ambient air which is sucked in at the front side exits the air box. In this context, the air inlet grille has a multiplicity of profiled strips which are arranged in at least two planes lying one behind the other in a main air inflow direction, wherein the profiled strips are spaced apart from one another within one plane and profiled strips lying in the various planes overlap laterally. The disclosure also relates to a cooling air system and to an electrical or electronic device.

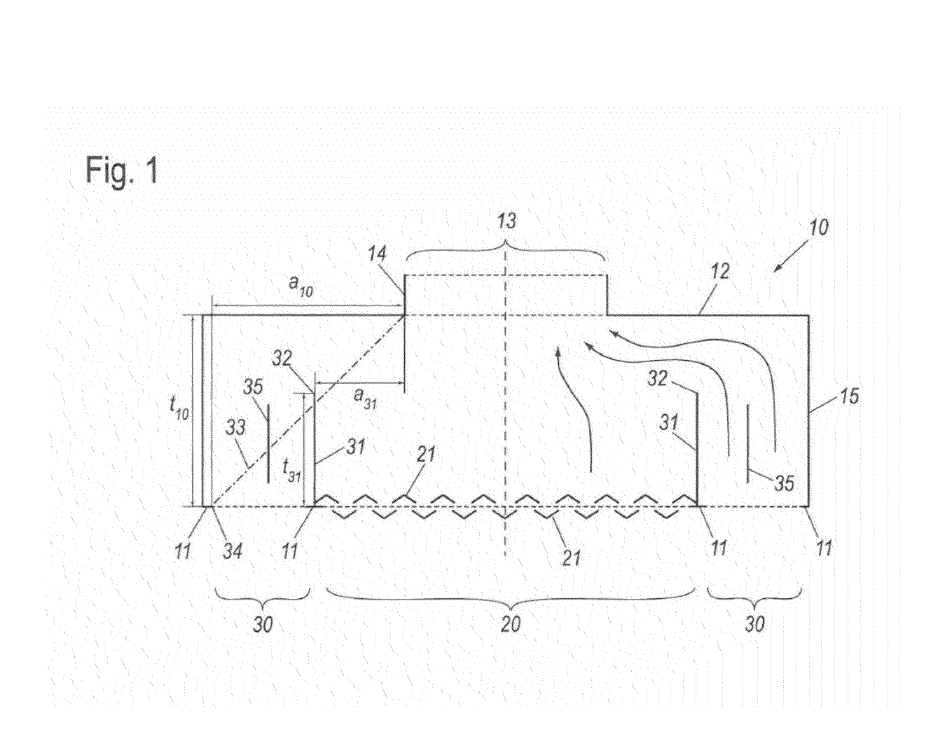

FIG. 1 shows a first example embodiment of a splash-water protection arrangement for a cooling air system of a housing of an electrical or electronic device in a schematic sectional illustration.

The splash-water protection arrangement shown can be used, for example, for a cooling air system of a power inverter of a photovoltaic system.

In one embodiment the splash-water protection arrangement is arranged on a vertical housing wall of a housing (not illustrated here). In such an installation position of the protection arrangement in the housing, FIG. 1 corresponds to a horizontal section through the protection arrangement.

The protection arrangement has an air box 10, fabricated, for example, from edged and/or stamped pieces of sheet metal which are welded or riveted to one another. The air boxes 10 have a front side 11 through which ambient air is sucked into the cooling air system. The splash-water protection arrangement is usually let into a wall of the housing of the electrical or electronic device to be cooled in such a way that the front side 11 is arranged parallel to, and in most cases also virtually flush with, the housing wall.

A rear side 12 of the air box 10, into which an air outlet opening 13 is inserted centrally, runs essentially parallel to the front side 11. The base surface of the front side 11 and of the rear side 12 are rectangular in the illustrated example embodiment, but they can also be embodied in a circular shape. The air outlet opening 13 is a round opening in one embodiment, but can also have another cross section. The air outlet opening 13 is bounded outwardly by an edge 14.

Furthermore, the air box 10 has side walls 15 which surround the air box 10 on both sides and in the upward and downward direction and largely seal it with respect to the housing of the electrical or electronic device, with the result that passage of air is possible only through the front side 11 and through the air outlet opening 13. In the event of a front side and rear side of the splash-water protection arrangement which are embodied in a circular fashion, only one side wall is present which surrounds the air box in a cylindrical shape. The distance from the front side 11 to the rear side 12, which is provided by the width of the side walls or of the merely one cylindrical side wall 15, is referred to below as depth t₁₀. The length of the front side 11 or of the rear side 12 in the plane of the drawing in FIG. 1 is referred to as the width of the air box 10. The extent of the air box 10 in a direction perpendicular to the plane of the drawing is referred to below as the height of the air box 10.

It is noted that the term “air outlet opening 13” refers to the splash-water protection arrangement or the air box 10 and not to the cooling air system. Within the cooling air system, the air outlet opening 13 is usually adjoined by a cooling air fan by means of which the air is sucked through the front side 11 of the air box 10, in order to conduct the air through the rest of the cooling air system. The rest of the cooling air system can be, for example, a cooling air duct which is routed through the housing and which conducts the cooling air past components which generate heat and are to be cooled. It is also possible for the cooling air blower to output the cooling air in a distributed fashion into the interior of the housing and for the cooling air to exit the housing again at one or more openings in the housing after the absorption of heat. Irrespective of the further configuration of the cooling air system, the object of the splash-water protection arrangement is to prevent the ingress of splash water into the air outlet opening 13 and therefore into the further course of the cooling air system.

According to the application, the air is let into the air box 10 through the front side 11 via an air inlet grille 20 as well as additionally via at least one air inlet opening 30, in the example embodiment in FIG. 1 two air inlet openings 30.

The air inlet grille 20 is arranged in a central region of the air box 10 with respect to its width and therefore lies directly opposite the air outlet opening 13. The width of the air inlet grille 20 exceeds the width of the air outlet opening 13, wherein the air inlet grille 20 projects laterally beyond the edge 14 of the air outlet opening 13 on both sides. In one embodiment, the air inlet grille 20 projects by approximately 50% of the width of the air outlet opening 13 beyond the air outlet opening 13 on both sides. For the case of a circular air outlet opening 13 and a circular air inlet grille 20, what has been stated above applies correspondingly to the diameter of the air outlet opening 13 or of the air inlet grille 20, instead of its width.

The air inlet grille 20 has a multiplicity of profiled strips 21 which, in the illustrated example embodiment, run essentially perpendicularly with respect to the plane of the drawing and are therefore arranged essentially vertically. In the illustrated example embodiment, the profiled strips 21 extend over the entire height of the air box 10. However, this is not absolutely necessary and also not provided for the case of a circular front side 11 and an air inlet grille 20 which is arranged centrally therein.

The profiled strips 21 are arranged in two planes which are spaced apart from one another. The planes run parallel to the front side 11 or rear side 12 of the air box 10. In a main air inflow direction, which runs perpendicularly with respect to the front side 11 of the air box 10 from the front side 11 to the rear side 12, the two planes are arranged one behind the other. Within each of the planes, the profiled strips 21 run in parallel—however at least largely parallel—and spaced apart from one another. Profiled strips 21 which run in various planes overlap laterally here, with the result that a projection of the profiled strips 21 in the main air inflow direction on to the air outlet opening 13 or the rear side 12 is uninterrupted.

In the main air inflow direction, splash water or sprayed water therefore cannot pass through the air inlet grille 20 on a direct path, but only with a deflection. Splash water or sprayed water which impacts against the air inlet grille 20 in the main air inflow direction, for example splash water droplets which are carried along with the airstream, can not follow the deflection of the airstream owing to their inertia and are intercepted by the profiled strips 21 and can run downwards on them. A run-off region which is not illustrated here conducts outwards the water which is intercepted in this way.

The deflection of the let-in air at the relatively small gaps between the individual profiled strips 21 leads, however, to a relatively high flow resistance of the air inlet grille 20. In order to achieve relatively low flow resistance, in the splash-water protection arrangement according to the application the air inlet opening 30 is provided next to the air inlet grille 20 on each side.

Since the air inlet grille 20 already projects laterally beyond the edge 14 of the air outlet opening 13, the projection of the air inlet opening 30 onto the rear side 12 in the main air inflow direction also lies outside the region of the air outlet opening 13.

Arranged on each side of the air inlet grille 20 between the air inlet grille 20 and the respective air inlet opening 30 is a dividing wall 31 which extends in the direction of the depth t₁₀ of the air box 10, from the front side thereof into the air box 10. The dividing walls 31 extend here over essentially the entire height of the air box 10. In the interior of the air box 10, the dividing walls 31 each have a free edge 32, wherein the distance from the front side 11 as far as the free edge 32 is referred to below as depth t₃₁ of the dividing walls 31. This depth t₃₁ is less than the depth t₁₀ of the air box, with the result that a gap remains through which air, which enters the air inlet opening 30, is deflected and conducted in the direction of the air outlet opening 13.

The side wall 15 and the rear side 12 of the air box 10 form, together with the dividing wall 31, an air labyrinth, wherein the dividing walls 31 prevent splash water which enters the air inlet opening 30 obliquely from being able to enter the air outlet opening 13 on a direct path. In order to bring this about, in one embodiment the free edge 32 lies along its entire length in the main air inflow direction behind each possible virtual straight connection 33 between a point on an edge 34 of the air inlet opening 30 and a point on the edge 14 of the air outlet opening 13.

In FIG. 1, an extreme situation in this regard is illustrated in the left-hand half of the air box 10. The virtual straight connection 33 which is shown runs from a point lying as far outside as possible on the edge 34 to a point lying as far outside as possible on the edge 14. Even splash water which enters so far on the outside and is directed onto the outer edge 14 of the air inlet opening 13 impacts on the dividing wall 31 and is intercepted thereby and conducted downward. Direct entry of splash water into the air outlet opening 13 is therefore prevented by the dividing wall 31.

A geometric relationship for the depth t₃₁ of the dividing wall 31 can be derived from the extreme situation illustrated in FIG. 1. Given a minimum depth of t′₃₁, the depth 32 lies precisely on the virtual straight connection 33. The following relationship then applies according to the intercept theorem:

(t₁₀-t′₃₁)/t₁₀=a₃₁/a₁₀,

where a₁₀ represents a distance, projected onto the rear wall 12, from the edge 14 of the air outlet opening 13 to the edge 34 of the air inlet opening 30, and a₃₁ represents a distance, projected onto the rear wall 12, from the edge 14 of the air inlet opening 30 as far as the free edge 32 of the dividing wall 31. From this relationship, the following results for the minimum depth t′₃₁ or the depth t₃₁ of the dividing wall 31:

t₃₁≧t′₃₁₌t₁₀(1−a₃₁/a₁₀).

In order to prevent splash water from impacting on the rear wall 12 too close to the edge 14 of the air outlet opening 13 and in order to allow for the fact that splash water follows to a certain extent the air flow directed towards the air outlet opening 13, it is advantageous to make a larger selection for the depth t₃₁ than is specified by the abovementioned relationship for the minimum depth t′₃₁. In one embodiment the depth t₃₁ is selected to be at least 10%, alternatively at least 20% greater than is specified by the minimum depth t′₃₁. What has been stated above applies appropriately also to the case of a circular front side, a circular air outlet opening, a circular air inlet grille and accordingly an annular air inlet opening. In this case, only a dividing wall which is embodied in a cylindrical shape is provided.

In one advantageous refinement of the disclosure, at least one air baffle 35 is additionally arranged, as is also illustrated in FIG. 1, on both sides of the air inlet grille 20, in each case between the dividing wall 31 and the side wall 15 which is adjacent thereto. The at least one air baffle 35 does not extend as far as the rear wall 12 but instead advantageously ends somewhat before the free edge 32 of the dividing wall 31 in the main air inflow direction. The at least one air baffle 35 is oriented essentially parallel to the dividing wall 31 and intersects the virtual straight connection 33 in the region behind the air inlet opening 30. The at least one air baffle serves merely to conduct the cooling air stream after its entry into the region behind the air inlet opening 30, but owing to its orientation and positioning it generates only a small, tolerable increase in the overall pressure loss. However, on the other hand, the baffle provides additional protection against obliquely impinging splash water and sprayed water.

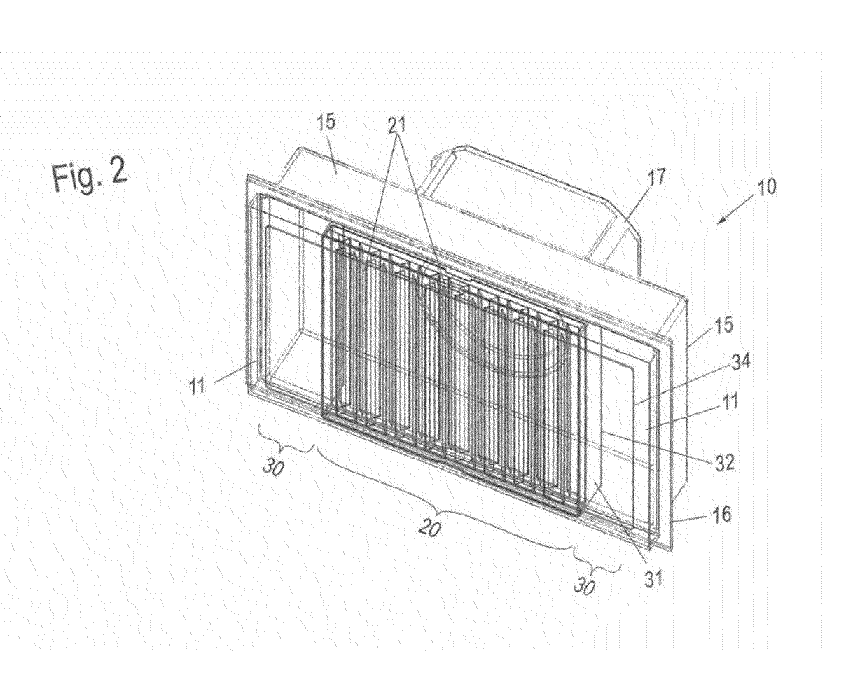

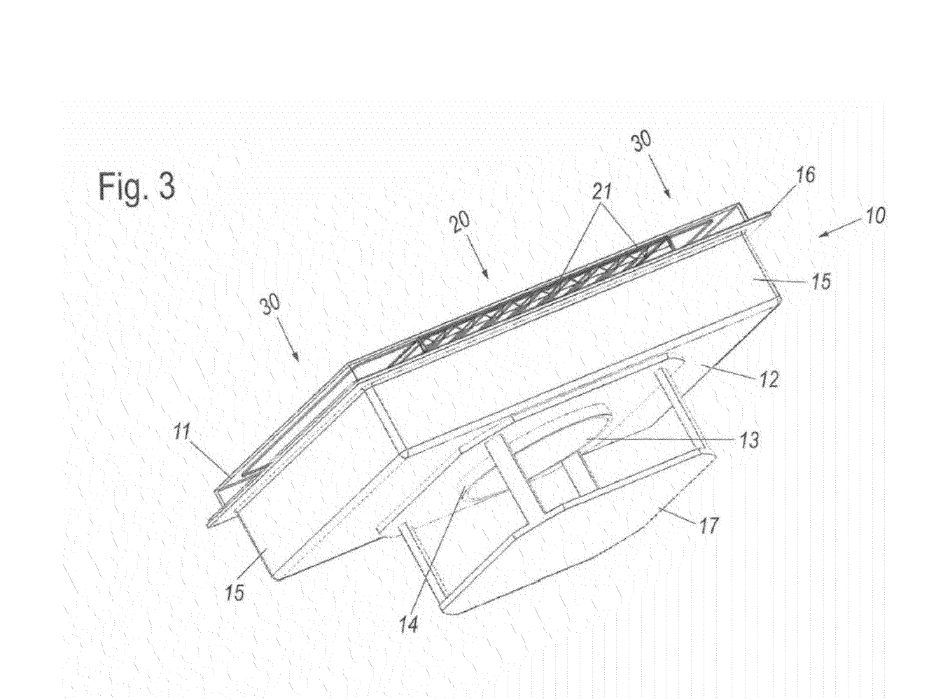

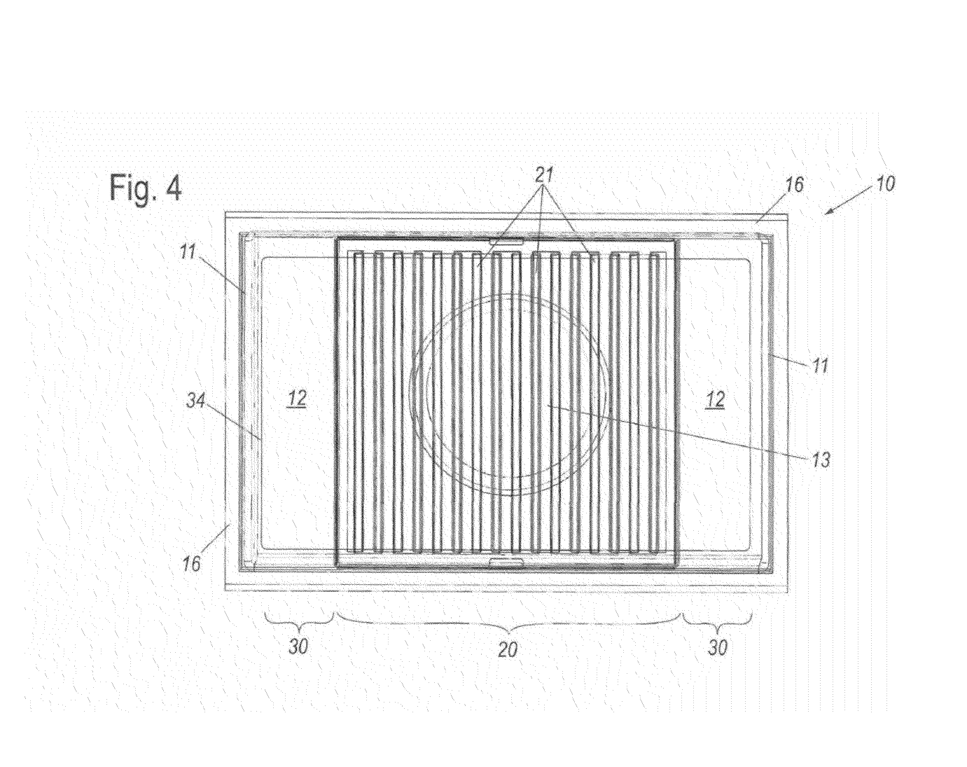

FIGS. 2 to 4 illustrate a second example embodiment of a splash-water protection arrangement. The same reference symbols characterize, in these figures, identically or identically acting elements to those in FIG. 1. FIGS. 2 and 3 show the splash-water protection arrangement, in each case in an isometric illustration, wherein FIG. 2 represents an oblique view from the front, and FIG. 3 represents an oblique view from the rear. Finally, FIG. 4 shows the splash-water protection arrangement in a plan view from the front.

As in the first example embodiment, in the splash-water protection arrangement of the second example embodiment a rectangular air box 10 is used which has, on its front side 11, a central air inlet grille 20 with an essentially square cross section and, in each case, air inlet openings 30 next to it in the lateral direction.

A round air outlet opening 13 is provided centrally on a rear side 12 of the air box 10. A circumferential installation collar 16, with which the splash-water protection arrangement can be inserted into a corresponding cutout in a side wall of a housing of an electrical or electronic device, if appropriate with intermediate positioning of a circumferential seal, is arranged in the front region of the side walls 15 of the air box 10.

As is shown in particular by FIG. 3, a securing means 17, which serves to accommodate a cooling air fan, is arranged on the rear wall 12 behind the air outlet opening 13. In the present case there is provision for the use of a radial fan which distributes air sucked in by the splash-water protection arrangement radially outwards into the housing of the electrical or electronic device. In an alternative refinement of the splash-water protection arrangement, the latter can be configured for use with an axial fan, wherein in this case there is no provision for air to be let out laterally, but instead axially, for example in that a cooling air duct or cooling air pipe or pipe connector would adjoin the air outlet opening 13.

According to the application, in each case a dividing wall 31 which points downwards into the air box in turn is provided between the venting grille 20 and the air inlet openings 30. The considerations adopted with respect to the example embodiment in FIG. 1, in terms of the dimensioning, in particular of the depth to which the dividing walls 31 extend into the air box 10, can be transferred analogously to the second example embodiment. In addition to the dividing wall 31, one or more air baffles are also optionally possible here, in a way comparable to the air baffles 35 in FIG. 1, in the region of the air inlet openings 30 which also provide additional protection, with only a slight increase in pressure loss, against the ingress of splash water or sprayed water impinging obliquely on the splash-water protection arrangement.

1. A splash-water protection arrangement for a cooling air system of a housing of an electrical or electronic device, comprising:
an air box comprising an air inlet grille on an outwardly facing front side and an air outlet opening on a rear side lying opposite the front side, through which air outlet opening ambient air sucked in at the front side exits the air box,
wherein the air inlet grille comprises a multiplicity of profiled strips which are arranged in at least two planes lying one behind the other in a main air inflow direction, wherein profiled strips lying within a plane are spaced apart from one another and wherein the profiled strips lying in the various planes overlap laterally,
wherein at least one air inlet opening is arranged next to the air inlet grille in the front side of the air box, and wherein a dividing wall which extends from the front side of the air box into an interior of the air box is arranged between the air inlet grille and the air inlet opening, through which dividing wall direct ingress of splash water or sprayed water through the air inlet opening into the air outlet opening is prevented.

2. The splash-water protection arrangement according to claim 1, in which the dividing wall extends so far into the interior of the air box that a free edge of the dividing wall lies in the main air inflow direction behind a virtual straight connection between a point at the edge of the air inlet opening and a point at the edge of the air outlet opening.

3. The splash-water protection arrangement according to claim 1, wherein an air inlet opening with an assigned dividing wall is arranged on each of the two sides next to the air inlet grille.

4. The splash-water protection arrangement according to claim 1, wherein the air inlet grille and the air outlet opening are arranged in planes that are parallel to one another, and wherein within the planes the air inlet grille is positioned laterally centred relative to the air outlet opening.

5. The splash-water protection arrangement according to claim 1, wherein the air inlet grille projects laterally beyond the air outlet opening.

6. The splash-water protection arrangement according to claim 5, wherein the air inlet grille projects laterally beyond the air outlet opening by at least 50% of the width of the air outlet opening.

7. The splash-water protection arrangement according to claim 1, wherein the profiled strips of the air inlet grille run parallel to one another.

8. The splash-water protection arrangement according to claim 7, wherein the profiled strips of the air inlet grille run vertically with respect to the direction of their longitudinal extent.

9. The splash-water protection arrangement according to claim 1, wherein the profiled strips of the air inlet grille have a groove-shaped profile, wherein the profiled strips are oriented in opposite directions to one another in the two planes with respect to their profile.

10. The splash-water protection arrangement according to claim 1, wherein at least one air baffle is arranged between at least one dividing wall and the side wall which is adjacent to the at least one dividing wall, wherein the at least one air baffle is oriented parallel to the dividing wall and is positioned in such a way that it has an intersection point with the virtual straight connection between a point at the edge of the air inlet opening and a point at the edge of the air outlet opening.

11. A cooling air system of a housing of an electrical or electronic device having a splash-water protection arrangement, comprising:
an air box comprising an air inlet grille on an outwardly facing front side and an air outlet opening on a rear side lying opposite the front side, through which air outlet opening ambient air sucked in at the front side exits the air box,
wherein the air inlet grille comprises a multiplicity of profiled strips which are arranged in at least two planes lying one behind the other in a main air inflow direction, wherein profiled strips lying within a plane are spaced apart from one another and wherein the profiled strips lying in the various planes overlap laterally,
wherein at least one air inlet opening is arranged next to the air inlet grille in the front side of the air box, and wherein a dividing wall which extends from the front side of the air box into an interior of the air box is arranged between the air inlet grille and the air inlet opening, through which dividing wall direct ingress of splash water or sprayed water through the air inlet opening into the air outlet opening is prevented.

12. A cooling air system according to claim 11, wherein the front side of the air box of the splash-water protection arrangement is formed by a section of a front wall, of a rear wall or of a side wall of the housing.

13. An electrical or electronic device having a housing comprising a cooling air system, comprising:
an air box comprising an air inlet grille on an outwardly facing front side and an air outlet opening on a rear side lying opposite the front side, through which air outlet opening ambient air sucked in at the front side exits the air box,
wherein the air inlet grille comprises a multiplicity of profiled strips which are arranged in at least two planes lying one behind the other in a main air inflow direction, wherein profiled strips lying within a plane are spaced apart from one another and wherein the profiled strips lying in the various planes overlap laterally,
wherein at least one air inlet opening is arranged next to the air inlet grille in the front side of the air box, and wherein a dividing wall which extends from the front side of the air box into an interior of the air box is arranged between the air inlet grille and the air inlet opening, through which dividing wall direct ingress of splash water or sprayed water through the air inlet opening into the air outlet opening is prevented.
